(19) United States
(12) Patent Application Publication
(10) Pub. No.: US 2007/0205425 A1
(43) Pub. Date: Sep. 6, 2007

(54) SEMICONDUCTOR LIGHT-EMITTING DEVICE

(76) Inventor: Mitsunori Harada, Tokyo (JP)

Correspondence Address: CERMAK KENEALY & VAIDYA, LLP, 515 EAST BRADDOCK RD SUITE B, Alexandria, VA, 22314, US

(21) Appl. No.: 11/470,719

(22) Filed: Sep. 7, 2006

(30) Foreign Application Priority Data
Sep. 8, 2005 (JP) 2005-260772

(51) Int. Cl. H01L 33/00

(52) U.S. Cl. 257/98

(57) ABSTRACT

In a conventional semiconductor light-emitting device having a semiconductor light-emitting element-mounted body and an optical lens which are located adjacent each other, interfacial peeling sometimes occurs at the contact interfaces between components when the device is subjected to outside temperature changes. This may lead to the deterioration of optical characteristics and the reduction in reliability of the device. In accordance with an aspect of the disclosed subject matter, a semiconductor light-emitting element-mounted body can be integrated with the optical lens via a soft resin spacer. Hence, the soft resin spacer can serve as a thermal stress relaxation layer located between the semiconductor light-emitting element-mounted body and the optical lens, which are integrated together. The thermal stress relaxation layer can possibly prevent peeling, caused by thermal stresses due to outside temperature changes, from occurring at the interfaces between the components.

This application claims the priority benefit under 35 U.S.C. § 119 of Japanese Patent Application No. 2005-260772 filed on Sep. 8, 2005, which is hereby incorporated in its entirety by reference.

1. Technical Field

The presently disclosed subject matter relates to a semiconductor light-emitting device, and in particular to a semiconductor light-emitting device which employs a semiconductor light-emitting element as a light source and has a unit for converting the wavelength of light.

2. Description of the Related Art

Examples of light-emitting devices, which employ a semiconductor light-emitting element as a light source, include LED light-emitting devices which employ a light emitting diode (LED) as a semiconductor light-emitting element. Such light-emitting devices are broadly categorized into two types, i.e., a vertical light-emitting device and a surface mount light-emitting device, according to their external shapes and the mounting methods therefor.

A vertical light-emitting device can be composed of, for example: a pair of lead frames arranged parallel to each other; an LED chip placed on the end portion of one of the lead frames; and a transparent resin which encapsulates one end portion of each of the lead frames so as to cover the LED chip and the lead frames. At this time, an upper electrode of the LED chip is connected to the other lead frame through a bonding wire or the like.

Each of the lead frames of the light-emitting device that are constituted as described above can be inserted into a through hole formed in a mounting substrate and soldered to the side of the mounting substrate that is opposite to a component side to thereby fix and mount the light-emitting device.

A surface mount light-emitting device can be composed of, for example: an insulating substrate; a pair of circuit patterns which are formed on respective opposing end portions on the front side of the substrate; a pair of circuit patterns which are formed so as to extend inwardly from the respective end portions and so as to oppose each other; an LED chip which is placed on an end portion of one of the inwardly extending circuit patterns; and a resin-encapsulated portion which is formed so as to cover the LED chip and a bonding wire with a transparent resin. In this instance, an upper electrode of the LED chip is connected to the other inwardly extending circuit pattern through the bonding wire.

A surface mount light-emitting device in another form can be composed of: a pair of plate-like lead frames; a resin-made package portion which has a recessed portion and is formed by insert molding such that the lead frames are exposed at the bottom surface of the recessed portion; an LED chip which is placed on one of the pair of lead frames exposed at the bottom surface of the recessed portion; and a resin-encapsulated portion which is formed by filling a transparent resin into the recessed portion of the package portion to cover the LED chip and bonding wire for the LED chip. In this example, an upper electrode of the LED chip is connected to the other lead frame through the bonding wire.

The circuit patterns extend through the resin-encapsulated portion to the outside, and the lead frames extend through the package of the light-emitting device to the outside. These circuit patterns or lead frames can be soldered to respective circuit patterns formed on a mounting substrate from a component side thereof, whereby the surface mount light-emitting device is fixed and mounted onto the mounting substrate.

As mentioned above, in the vertical light-emitting devices and the surface mount light-emitting devices, the LED chip and the bonding wire are encapsulated with a transparent resin. This is done for various purposes, including protecting the LED chip from moisture, dust, gas, and the like when used in an external environment, as well as for protecting the bonding wire from mechanical stresses caused by vibration, shock, or the like. Furthermore, the transparent resin forms an interface with a light-emitting surface of the LED chip. In this instance, by utilizing the difference in refractive index between the transparent resin and a semiconductor material forming the light emitting surface of the LED chip, the light emitted from the LED chip can be efficiently emitted into the transparent resin from the light-emitting surface of the LED chip.

The LED chip can have a cubic shape having a side of, for example, about 0.5 mm and can emit a small amount of light, and thus the optical properties thereof are close to those of a point light source. Therefore, the resin-encapsulated portion of a light-emitting device, which employs the LED chip having such properties as a light source, is configured to serve as a spheric or aspheric convex lens which is formed of a transparent resin and is positioned above the LED chip. In this instance, the light emitted from the LED chip is guided in the transparent resin and reaches the lens surface of the transparent resin. Thus, the above configuration allows this light to be efficiently emitted to the outside and also allows the light emitted to the outside to be collected in one direction to thereby increase the axial luminous intensity of the light-emitting device.

In such a vertical light-emitting device, both favorable light extraction efficiency and favorable light-gathering ability can be simultaneously achieved by forming the resin-encapsulated portion into a cannon-ball type lens shape. This can be accomplished by the molding process of the transparent resin. Meanwhile, the surface mount light-emitting devices are subjected to the constraint that the size and height thereof should be small, which is one of the aspects of these types of LEDs. Hence, even when the resin-encapsulated portion is formed into a lens shape, an adequate distance between the LED chip and the lens and an adequate lens diameter as provided in the cannon-ball type LED often cannot be secured. Therefore, the attained light gathering efficiency is sometimes not comparable to that of the cannon-ball type LEDs, and the difficulty lies in achieving an axial luminous intensity comparable to that of the cannon-ball type LEDs.

Accordingly, some light-emitting devices have been proposed which are surface mount light-emitting devices and have improved light extraction efficiency and light-gathering ability by forming a lens having a diameter comparable to that of the vertical light-emitting devices.

This type of light-emitting device is shown in FIG. 1. First, a resin for encapsulation is filled into an encapsulation case 50 having a spherical or aspherical inner bottom surface shape to form an encapsulation resin portion 51. An LED chip is place on a recessed portion of a resin stem 52 in advance and is encapsulated with a resin. Then a surface mount LED 53 constructed as generally described above is immersed into the resin in the encapsulation resin portion 51 with the upper surface thereof down. Further, the resin is heat-cured with lead frames 54 serving as a stopper abutted on the encapsulation case 50. After the heat-curing, the cured resin is removed from the encapsulation case 50, and the lead frames 54 are cut and subjected to forming as appropriate to thereby complete a light-emitting device shown in FIG. 2.

The thus-produced light-emitting device can be soldered onto a mounting substrate from a component side. In addition, in the encapsulation resin portion 51, a spheric or aspheric convex lens 56 having a diameter larger than the size of the resin stem 52 can be formed above an LED chip 55 (see, for example, Japanese Patent No. 3492178).

Meanwhile, light-emitting devices have been commercialized in which a phosphor is excited with the light emitted from an LED chip to convert the wavelength thereof, thereby emitting light having a color that is different from that of the light emitted from the LED chip. In this case, the wavelength of the emitted light is converted through a wavelength conversion material such as a phosphor. For example, in the case where the light emitted from the chip is blue light, when a fluorescent material is employed which converts the wavelength of the blue light to yellow (complementary color of blue) light, a light-emitting device can be configured to emit near white light formed by an additive process of the blue light and the yellow light. Based on such a system, various light-emitting devices can be realized by combinations of emitted light (for example, blue light, UV light, or the like) with corresponding wavelength conversion materials (materials converting incident light to yellow, green, red, or other color light).

A light-emitting device employing the abovementioned wavelength conversion materials can be constituted as follows. First, an LED chip is placed on a recessed portion of a resin stem. Subsequently, one or more wavelength conversion materials such as a phosphor are mixed with a transparent resin, and the resin is injected into the recessed portion to form a resin-encapsulated portion. The thus-constructed surface mount light-emitting device is directly integrated with a transparent resin which forms a spheric or aspheric convex lens. In this instance, interfaces which do not involve chemical bonding are present between the resin-encapsulated portion and the transparent resin forming the lens and between the resin stem and the transparent resin forming the lens.

The operating environment temperature of a general light-emitting device is set to about −20° C. to +80° C. However, in particular for a light-emitting device to be installed in a vehicle, a wider operating temperature range is required. For example, such a light-emitting device is required to be stably operated in the temperature range of −40° C. to 100° C.

However, in the light-emitting device constituted as described above, each of the components forming the interfaces is repeatedly subjected to thermal expansion and contraction caused by environmental temperature changes. In this instance, when the materials constituting the components each have the same thermal expansion coefficient, all the components are repeatedly subjected to thermal expansion and contraction in an integrated manner. However, when the thermal expansion coefficients of these materials are different from each other, a difference occurs in the amount of thermal expansion or contraction between the components, which generates stresses associated with the difference. Hence, the possibility arises that peeling occurs at the interface, especially when there is no chemical bonding at the interface. In particular, interfacial peeling tends to occur when the interface is formed from high hardness materials.

A gap is formed due to interfacial peeling, and an air layer in the gap causes a loss of light guided therethrough. In time, this leads to the deterioration of optical characteristics of a light-emitting device (such as the reduction in luminous intensity), and thus the reliability of the product is also impaired.

### SUMMARY

Accordingly, the presently disclosed subject matter was developed in view of the above mentioned issues and in view of various other reasons. In accordance with an aspect of the disclosed subject matter, a high reliability semiconductor light-emitting device can include an optical lens that is integrally formed with a semiconductor light-emitting element-mounted body encapsulated with resin. In the semiconductor light-emitting device, interfacial peeling may be prevented from occurring at a contact interface formed by the integration, even when the device is subjected to environmental temperature changes, and deterioration of optical characteristics with time may not occur and may be prevented.

Another aspect of the presently disclosed subject matter includes a semiconductor light-emitting device that can be composed of the following: a semiconductor light-emitting element-mounted body configured to include a circuit substrate having a circuit provided on at least one surface thereof; a reflector provided on the circuit substrate and having a recessed portion in which the surface of the circuit substrate serves as an inner bottom surface thereof; a semiconductor light-emitting element provided in the recessed portion; a resin-encapsulated portion formed by filling a resin material into the recessed portion; an optical lens provided in a light emission direction and forward of the semiconductor light-emitting element; and, a transparent soft resin spacer portion which can be provided between a light incident surface of the optical lens and a light emission surface of the semiconductor light-emitting element-mounted body to thereby integrate the optical lens with the semiconductor light-emitting element-mounted body.

In the above-described semiconductor light-emitting device, the resin-encapsulated portion may contain a wavelength conversion material.

In addition, an outer peripheral surface of the reflector may have a shape extending outwardly in the light emission direction. In this instance, the outer peripheral surface can be inclined outwardly within the range of 2 to 30° with respect to an optical axis of the semiconductor light-emitting element. Furthermore, in this instance, the thickness of the transparent soft resin spacer portion can be 30% or more of a distance between the surface of the circuit substrate and an upper end surface of the reflector.

In the above-described semiconductor light-emitting device, the reflector may have at least two outer peripheral surface portions having different diameters. In this instance, the outer diameter of a lower outer peripheral surface portion on the side of the circuit substrate may be smaller than the outer diameter of an upper outer peripheral surface portion on the opening side of the reflector. Furthermore, the difference in outer diameter between the upper outer peripheral surface portion and the lower outer peripheral surface portion of the reflector can be within the range of 0.1 to 2.0 mm. In some cases it can be advantageous to have a distance between the light incident surface of the optical lens and a step portion in the outer peripheral surface of the reflector be within the range of 0.1 to 1.0 mm.

In the above-described semiconductor light-emitting device, the optical lens may have a lens surface and a light incident surface on the side opposite to the lens surface and have a recessed portion on the light incident surface. In this instance, the distance between a bottom surface of the recessed portion of the optical lens and an upper end surface of the reflector may be within the range of 0.1 to 1.0 mm.

Another aspect of the presently disclosed subject matter includes a method for manufacturing the semiconductor light-emitting device as described above. The method can include: supplying a resin material forming the transparent soft resin spacer portion to the inside of the recessed portion of the optical lens and placing the optical lens at a predetermined position; pressing the reflector of the semiconductor light-emitting element-mounted body against the resin material of the transparent soft resin spacer portion to bury the reflector in the resin material; heat-curing the resin material of the transparent soft resin spacer portion while keeping a bottom surface in the recessed portion of the optical lens and an upper end surface of the reflector separated by a predetermined distance.

Still another aspect of the presently disclosed subject matter includes a semiconductor light-emitting device that includes: a semiconductor light-emitting element-mounted body configured to include a circuit substrate having a circuit provided on at least one surface thereof, a reflector provided on the circuit substrate and having a recessed portion in which the surface of the circuit substrate serves as an inner bottom surface thereof, a semiconductor light-emitting element provided in the recessed portion, and a resin-encapsulated portion formed by filling a resin material into the recessed portion; an optical lens provided in a forward light emission direction of the semiconductor light-emitting element and having a flange in the light incident side periphery thereof; a first transparent soft resin spacer portion provided between a light incident surface of the optical lens and a light emission surface of the semiconductor light-emitting element-mounted body to thereby integrate the optical lens with the semiconductor light-emitting element-mounted body; and a second transparent soft resin spacer portion provided between the flange and the circuit substrate.

In the above-described semiconductor light-emitting device, the resin-encapsulated portion may contain a wavelength conversion material.

In the above-described semiconductor light-emitting device, the optical lens may have a lens surface and a light incident surface located on a side opposite to the lens surface, a recessed portion can be located on a side of the light incident surface.

In the above-described semiconductor light-emitting device, the distance between a bottom surface of the recessed portion of the optical lens and an upper end surface of the reflector may be within the range of 0.1 to 1.0 mm.

Light scattering particles and/or dye can be mixed with any of the transparent soft resin spacer portions.

Still another aspect of the presently disclosed subject matter includes a method for manufacturing the above-described semiconductor light-emitting devices. The method can include: supplying a resin material forming the first transparent soft resin spacer portion onto the reflector and the resin encapsulated portion and placing the semiconductor light-emitting element-mounted body at a predetermined position; pressing the resin material of the first transparent soft resin spacer portion with the light incident surface of the lens; and heat-curing the resin material of the first transparent soft resin spacer portion while keeping a bottom surface of the recessed portion of the optical lens and an upper end surface of the reflector separated by a predetermined distance.

Still another aspect of the presently disclosed subject matter is a semiconductor light-emitting device that can be configured to include: a semiconductor light-emitting element-mounted body configured to include a circuit substrate having a circuit provided on at least one surface thereof, a reflector provided on the circuit substrate and having a recessed portion in which the surface of the circuit substrate serves as an inner bottom surface thereof, a semiconductor light-emitting element provided in the recessed portion, and a resin-encapsulated portion formed by filling a resin material into the recessed portion; an optical lens provided in a forward light emission direction of the semiconductor light-emitting element; and a transparent soft resin spacer portion provided between a light incident surface of the optical lens and a light emission surface of the semiconductor light-emitting element-mounted body to thereby integrate the optical lens with the semiconductor light-emitting element-mounted body, wherein the optical lens has a recessed portion on the side of the light incident surface thereof which portion has at least two inner peripheral surface portions having different inner diameters, and that, among the at least two inner peripheral surface portions, an inner peripheral surface portion on an opening side of the recessed portion of the optical lens has an inner diameter larger than the inner diameter of an inner peripheral surface portion on a lens surface side.

In the above-described semiconductor light-emitting device, among the at least two inner peripheral surface portions, the smaller inner diameter inner peripheral surface portion may have an inner diameter larger than the outer diameter of an upper end surface of the reflector.

A transparent soft resin spacer portion may be provided in the recessed portion of the optical lens, for example, the portion having the smaller inner diameter inner peripheral surface portion. In this instance, the transparent soft resin spacer portion that is located in the recessed portion of the optical lens which has the smaller inner diameter inner peripheral surface portion may contain a wavelength conversion material.

Still another aspect of the presently disclosed subject matter includes a method for manufacturing the above-described semiconductor light-emitting devices. The method can include: supplying a resin material forming the transparent soft resin spacer portion onto the reflector and the resin encapsulated portion and placing the semiconductor light-emitting element-mounted body at a predetermined position; pressing the resin material of the transparent soft resin spacer portion with the light incident surface of the lens; and heat-curing the resin material of the transparent soft resin spacer portion while keeping a bottom surface of the recessed portion of the optical lens and an upper end surface of the reflector separated by a predetermined distance.

In the above-mentioned semiconductor light-emitting device, the resin material of the transparent soft resin spacer portion may be a soft silicone resin.

In the semiconductor light-emitting device in accordance with the disclosed subject matter, a reflector having a recessed portion can be placed on a circuit substrate, and a semiconductor light-emitting element-mounted body formed by encapsulating. A transparent resin can contain a wavelength conversion material, and a semiconductor light-emitting element can be mounted on the recessed portion. Then, the semiconductor light-emitting element-mounted body can be integrated with an optical lens via a soft resin spacer.

The soft resin spacer serves as a thermal stress relaxation layer provided between the semiconductor light-emitting element-mounted body and the optical lens which are integrated together. The thermal stress relaxation layer can provide several different effects, including the prevention of peeling caused by thermal stresses at the time of environmental temperature changes (the peeling typically occurring at the interfaces between the components). Thus, a semiconductor light-emitting device having a high reliability and high light extraction efficiency can be realized.

### BRIEF DESCRIPTION OF THE DRAWINGS

These and other characteristics, features, and advantages of the disclosed subject matter will become clear from the following description with reference to the accompanying drawings, wherein:

FIG. 1 is a schematic view illustrating a method for manufacturing a conventional semiconductor light-emitting device;

FIG. 2 is a cross-sectional view of the conventional semiconductor light-emitting device of FIG. 1;

FIGS. 3(a)-(g) depict a manufacturing process diagram for an embodiment of a semiconductor light-emitting element-mounted body employed in a semiconductor light-emitting device made in accordance with principles of the disclosed subject matter;

FIGS. 4(a)-(c) depict a manufacturing process diagram for an embodiment of a semiconductor light-emitting device made in accordance with principles of the disclosed subject matter;

FIG. 5 is a cross-sectional view illustrating a working example of a semiconductor light-emitting device made in accordance with principles of the disclosed subject matter;

FIG. 6 is a cross-sectional view illustrating another working example of a semiconductor light-emitting device made in accordance with principles of the disclosed subject matter;

FIGS. 7(a)-(d) depict a manufacturing process diagram illustrating still another working example of a semiconductor light-emitting device made in accordance with principles of the disclosed subject matter;

FIG. 8 is a cross-sectional view illustrating the working example of the semiconductor light-emitting device manufactured as shown in FIGS. 7(a)-(d);

FIGS. 9(a)-(d) depict a manufacturing process diagram for another working example of a semiconductor light-emitting device made in accordance with principles of the disclosed subject matter;

FIG. 10 is a cross-sectional view illustrating the working example of the semiconductor light-emitting device manufactured as shown in FIGS. 9(a)-(d);

FIGS. 11(a)-(c) depict a manufacturing process diagram for still another working example of a semiconductor light-emitting device made in accordance with principles of the disclosed subject matter;

FIG. 12 is a cross-sectional view illustrating the working example of the semiconductor light-emitting device manufactured as shown in FIGS. 11(a)-(c);

FIGS. 13(a)-(c) depict a manufacturing process diagram for yet another working example of a semiconductor light-emitting device made in accordance with principles of the disclosed subject matter; and

FIG. 14 is a cross-sectional view illustrating the working example of the semiconductor light-emitting device manufactured as shown in FIGS. 13(a)-(c);

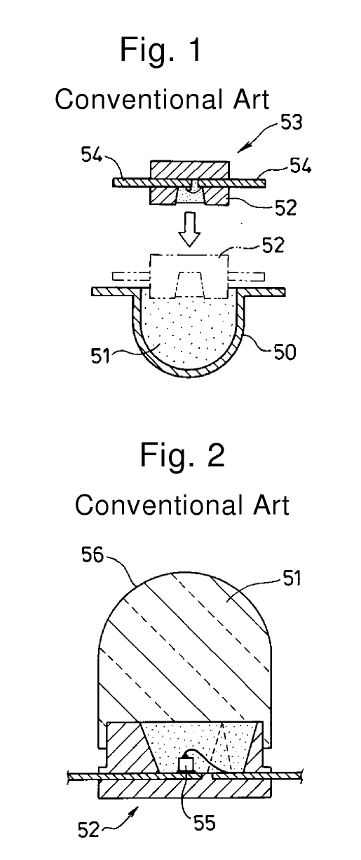

### DETAILED DESCRIPTION OF EXEMPLARY EMBODIMENTS

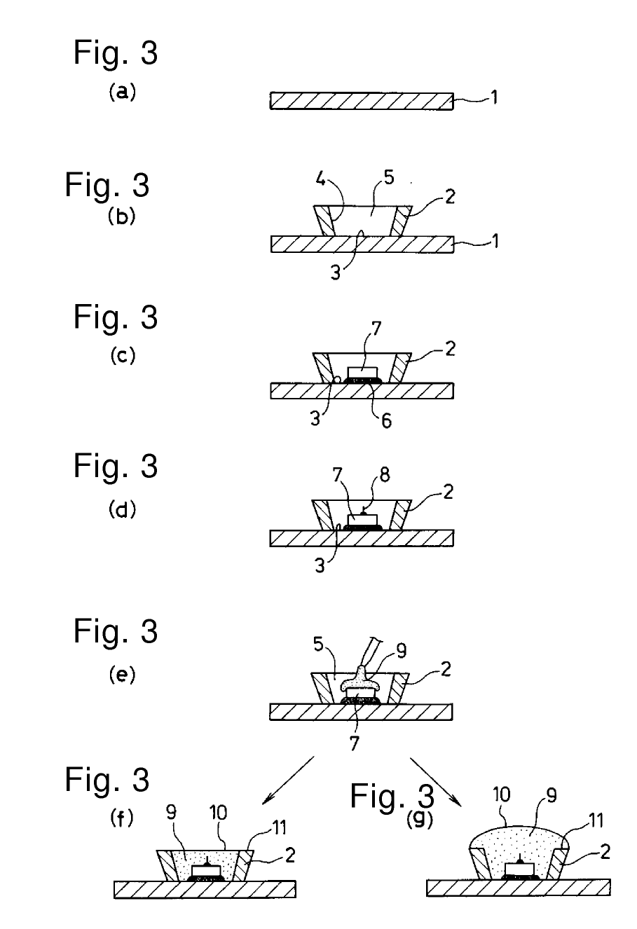

Exemplary embodiments of the presently disclosed subject matter will be described in detail with reference to FIGS. 3 to 12. The exemplary embodiments described hereinafter are specific examples of the disclosed subject matter, and thus various technical features and characteristics are added thereto. However, the scope of the present invention of the disclosed subject matter is not limited to the exemplary embodiments.

A semiconductor light-emitting device made in accordance with principles of the disclosed subject matter can be configured to include a semiconductor light-emitting element-mounted body, an optical lens, and a transparent soft resin spacer.

The semiconductor light-emitting element-mounted body is one of the components of the semiconductor light-emitting device, and first the manufacturing steps thereof are described with reference to FIGS. 3(a)-(g).

In FIG. 3(a) a circuit substrate 1 on which electrode wiring has been preformed can be provided. The circuit substrate 1 can include a base which is formed of a material including one or more of the following: a ceramic such as aluminum oxide, aluminum nitride, silicon carbide, silicon nitride, or zirconium oxide; a resin such as glass epoxy or polyimide; a metal such as iron or aluminum; and/or paper phenol. In particular, the base of the circuit substrate 1 can be formed of a ceramic having excellent thermal conductivity. The electrode wiring (not shown) can be formed on the surface of the base substrate or both on the surface of and inside the base substrate. Furthermore, electrodes for feeding electric power supplied from the outside to the semiconductor light-emitting element-mounted body can be provided on one or more surfaces of the base substrate.

In FIG. 3(b) a reflector 2 can be provided on a surface of the circuit substrate 1. The surface of the circuit substrate 1 serves as an inner bottom surface 3 of the reflector 2, and the reflector 2 is constituted by a wall rising from the inner bottom surface 3. Specifically, the reflector 2 has a bowl-shaped recessed portion 5 which has an inner peripheral surface 4 extending outwardly toward an upper opening. Furthermore, at least the inner peripheral surface 4 can have a high reflectivity. In order to achieve this, the reflector 2 may be formed of a reflective resin material, a reflective metal material, or the like. Alternatively, the reflector 2 can be formed of a non-reflective resin material, metal material, ceramic material, or the like and may be subjected to reflection processing such as plating or vapor deposition to form a reflection surface. In this instance, when the reflector 2 is formed from a metal material, the reflector 2 may be fixed to a circuit substrate via, for example, silver solder or a high thermal conductivity adhesive.

In FIG. 3(c) a semiconductor light-emitting element 7 is mounted, via a conductive member 6 (such as an Au—Sn alloy, lead free solder, silver solder, or the like), on one of a pair of separate and independent electrode wirings positioned on the inner bottom surface 3 of the reflector 2. In this manner, electrical continuity is provided between the electrode wiring and a lower electrode of the semiconductor light-emitting element 7.

In FIG. 3(d) an upper electrode of the semiconductor light-emitting element 7 is connected via a bonding wire 8 (such as Au, Al, Cu, or other know type of wire) to the other electrode wiring positioned on the inner bottom surface 3 of the reflector 2. In this manner, electrical continuity is provided between the electrode wiring and the upper electrode of the semiconductor light-emitting element 7.

In FIG. 3(e) a predetermined amount of a transparent resin 9 is injected into the recessed portion 5 of the reflector 2 by use of a supplying unit for supplying a predetermined amount of liquid (such as a dispenser) to encapsulate the semiconductor light-emitting element 7 and the bonding wire 8 with the resin 9. Here, one or more wavelength conversion materials such as a phosphor can be mixed with the transparent resin 9, as appropriate.

Note that the injection amount of the transparent resin 9 may be adjusted such that an upper surface 10 of the transparent resin 9 is approximately flush with an upper end surface 11 of the reflector 2, as shown in FIG. 3(f). Alternatively, the injection amount of the transparent resin 9 may be adjusted such that the upper surface 10 of the transparent resin 9 swells from the upper end surface 11 of the reflector 2, as shown in FIG. 3(g).

In the former case, the semiconductor light-emitting element-mounted body shown in FIG. 3(f) can be sent for subsequent processing after the transparent resin 9 is heat-cured. On the other hand, in the latter case, the semiconductor light-emitting element-mounted body shown in FIG. 3(g) can be sent for subsequent processing with the transparent resin 9 remaining uncured.

Next, a working example of a semiconductor light-emitting device and a method for manufacturing the same will be described. The semiconductor light-emitting device may be composed of: the semiconductor light-emitting element-mounted body completed through the abovementioned manufacturing steps; and other components, e.g., an optical lens and a transparent soft resin spacer.

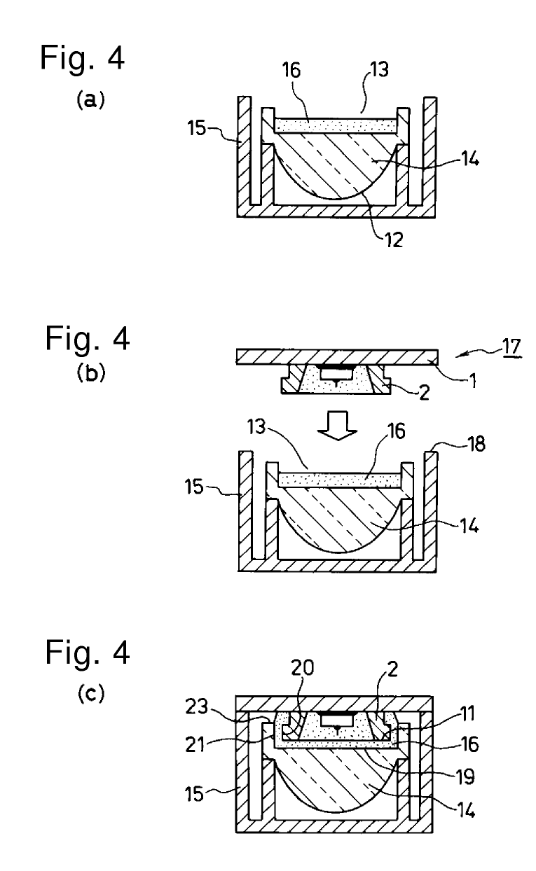

FIGS. 4(a)-(c) illustrate an example of a method for manufacturing a semiconductor light-emitting device in accordance with the presently disclosed subject matter.

In FIG. 4(a) an optical lens 14 employed in the depicted working example has a recessed portion 13 formed on the side opposite to a lens surface 12. During manufacture, this optical lens 14 can be set on a jig 15 with the lens surface 12 facing downward. In this state, a liquid transparent soft resin spacer 16 is injected into the recessed portion 13 positioned in the upper portion of the optical lens 14.

In FIG. 4(b) a semiconductor light-emitting element-mounted body 17 (for example, as completed through the steps of FIG. 3) can be lowered with an emission surface of the light-emitting element facing downward until the circuit substrate 1 abuts on an upper end 18 of a support wall of the jig 15. Here, in this working example, the semiconductor light-emitting element-mounted body shown in FIG. 3(f) is employed.

In FIG. 4(c) the jig 15 is shown as being constructed such that the reflector 2 is buried in the uncured transparent soft resin spacer 16 when the circuit substrate 1 is lowered and abuts on the upper end 18. In this state, the transparent soft resin spacer 16 fills the gap between the upper end surface 11 of the reflector 2 and an inner bottom surface 19 of the recessed portion 13 and the gap between an outer peripheral surface 20 of the reflector 2 and an inner peripheral surface 21 of the recessed portion 13. Furthermore, the transparent soft resin spacer 16 that overflows from the recessed portion 13 rises due to the surface tension of the resin along a portion of the outer peripheral surface 20 of the reflector 2, which portion is located higher than an end surface 23 of the optical lens 14. Hence, the outer peripheral surface 20 can be covered with the transparent soft resin spacer 16. With this state is maintained, the entire jig 15 can be heated in order to cure the transparent soft resin spacer 16. Subsequently the transparent soft resin spacer 16 can be removed from the jig 15.

One way to achieve the above state is to form the transparent soft resin spacer 16 of a resin material which can have a certain softness characteristic that is softer than the optical lens 14 in the state of use of the completed semiconductor light-emitting device. In an exemplary embodiment, the optical lens 14 may be formed of a transparent hard resin (for example, having a Shore hardness of about 50, such as epoxy resins, polycarbonate resins, or the like), and the transparent soft resin spacer 16 may be formed of a transparent gel resin having a rubber hardness in the range of 0 to 50 in accordance with JIS A rubber hardness. Furthermore, the injected amount of the transparent soft resin spacer 16 may be adjusted to an amount necessary and sufficient for covering the entire outer peripheral surface 20 of the reflector 2 with the transparent soft resin spacer 16. The soft resin spacer 16 can overflow from the recessed portion 13 when the reflector 2 is embedded in the transparent soft resin spacer 16.

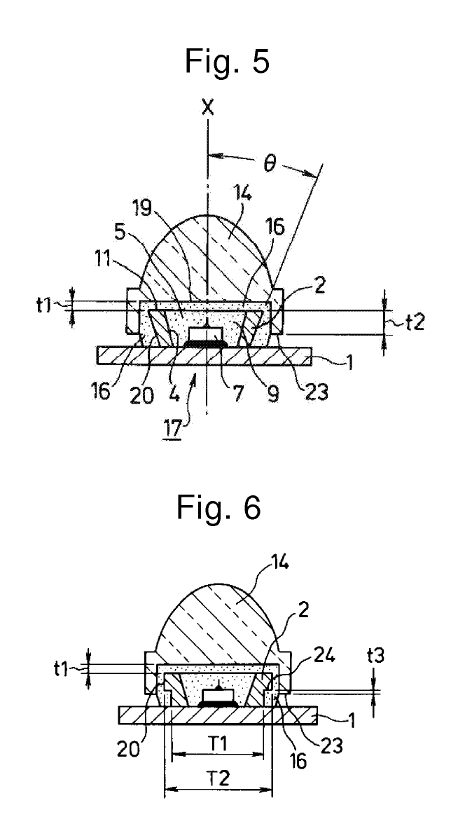

FIG. 5 shows a cross-sectional view of the semiconductor light-emitting device produced by means of the above described manufacturing method. The reflector 2 provided on the circuit substrate 1 of the semiconductor light-emitting element-mounted body 17 can be integrated with the optical lens 14 via the transparent soft resin spacer 16.

The reflector 2 has the outer peripheral surface 20 and the inner peripheral surface 4 which extends outwardly toward the upper opening of the recessed portion 5 of the reflector 2. The inclination angle θ of the outer peripheral surface 20 with respect to an optical axis X of the semiconductor light-emitting element 7 can be within the range of 2 to 30° and possibly can be within the range of 5 to 15°, which is optimal in some conditions/applications. The anchor effect of the transparent soft resin spacer 16 that rises along the outer peripheral surface 20 can be maximized by the inclination of the outer peripheral surface 20.

In this instance, a thickness t1 is defined as the thickness of the transparent soft resin spacer 16 filling the gap between the inner bottom surface 19 of the recessed portion 13 of the optical lens 14 and the upper end surface 11 of the reflector 2. The thickness t1 can be computed based on the possible temperature difference with the outer environment, the thickness, the linear expansion coefficient of the transparent soft resin spacer 16 itself, and the linear expansion coefficient for the components forming interfaces with the spacer 16. The computed thickness t1 can be within the range of 0.1 to 1.0 mm and possibly within the range of 0.2 to 0.5 mm. In this instance, a distance t2 is defined as the distance between a lowermost surface 23 of the optical lens 14 and the upper end surface 11 of the reflector 2. This distance t2 can be 30% or more of the distance between the surface of the circuit substrate 1 and the upper end surface 11 of the reflector 2, and possibly 50% or more of this distance to achieve a large anchor effect.

FIG. 6 illustrates another working example of the semiconductor light-emitting device manufactured by means of the same manufacturing method. In this working example, the outer peripheral surface 20 of the reflector 2 has two surface portions having different diameters (stepped configuration).

In this example, the outer peripheral surface 20 of the reflector 2 has a stepped configuration, and the lower surface portion near the circuit substrate 1 has a diameter T1 smaller than a diameter T2 of the upper surface portion near the opening of the reflector 2. Specifically, the difference between T1 and T2 (T2−T1) can be within the range of 0.1 to 2.0 mm and possibly within the range of 0.3 to 0.8 mm. The anchor effect of the transparent soft resin spacer 16 that rises along the outer peripheral surface 20 can be maximized by providing the stepped configuration of the outer peripheral surface 20. In this instance, a distance t3 is defined as the distance between the lowermost surface 23 of the optical lens 14 and the position of the step 24 of the outer peripheral surface 20 of the reflector 2. This distance t3 can be within the range of 0.1 to 1.0 mm and possibly within the range of 0.2 to 0.5 mm.

As described above, in the semiconductor light-emitting devices of the above-described working examples, the reflector portion of the semiconductor light-emitting element-mounted body can be integrated with the optical lens via the transparent soft resin spacer. Therefore, the transparent soft resin spacer, which has an anchor effect and a stress relaxation function, can prevent peeling (possibly caused by thermal stresses due to outside temperature changes) from occurring at the interfaces between the components, whereby a semiconductor light-emitting device having high light extraction efficiency and high reliability can be realized. Namely, these feature and characteristics may be achieved by the soft resin spacer absorbing and/or relaxing the stress occurring at the interface between adjacent materials.

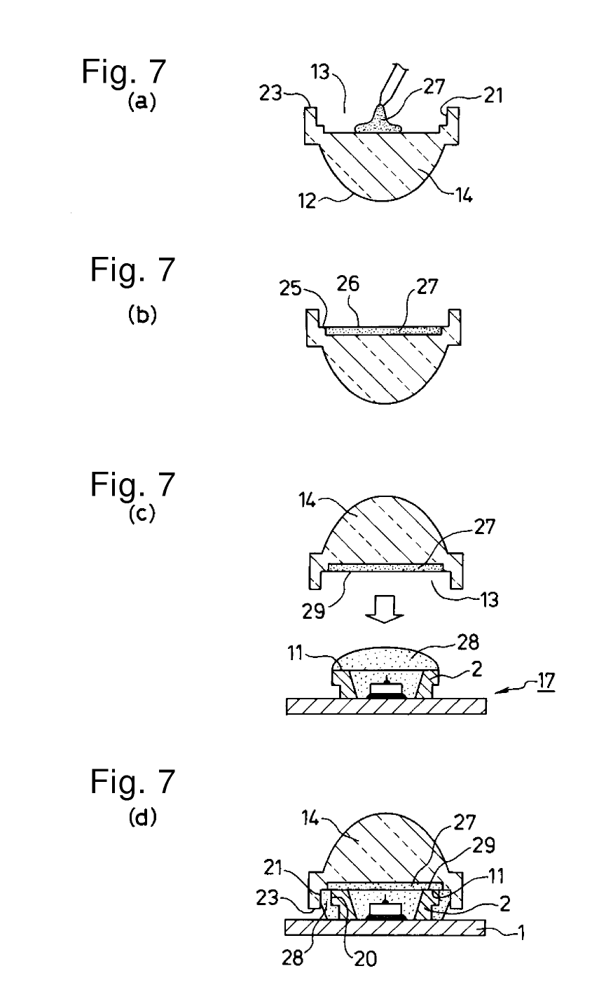

FIGS. 7(a)-(d) illustrate another working example of a method for manufacturing a semiconductor light-emitting device that is made in accordance with principles of the presently disclosed subject matter.

In FIG. 7(a) the optical lens 14 has a recessed portion 13 formed on the side opposite to the lens surface 12, and the recessed portion 13 has an inner peripheral surface 21 of stepped configuration having different diameters. This optical lens 14 can be set on a jig (not shown) with the lens surface 12 facing downward. In this instance, in the inner peripheral surface 21 of the stepped configuration, the diameter of the surface portion near the lens surface 12 is smaller than the diameter of the surface portion near the end surface 23 of the optical lens 14. A first transparent soft resin spacer 27 in a liquid state can be injected into a region of the recessed portion 13 which is closer to the lens surface 12.

In FIG. 7(b), the amount of the injected first transparent soft resin spacer 27 can be adjusted such that an upper surface 26 of the first transparent soft resin spacer 27 is approximately flush with a step 25 of the inner peripheral surface 21. With this state maintained, heat can be applied thereto to cure the first transparent soft resin spacer 27.

In FIG. 7(c) a second transparent soft resin spacer 28 is applied to a light emitting surface of the semiconductor light-emitting element-mounted body 17 (as shown in FIG. 3(f)) which, for example, can be completed through the steps of FIG. 3 such that the resin spacer 28 swells into a convex shape. As mentioned above, the optical lens 14 has a first transparent soft resin spacer 27 provided in the region of the recessed portion 13 which is closer to the lens surface 12. This optical lens 14 is lowered with the recessed portion 13 facing the second transparent soft resin spacer 28 until a surface 29 of the first transparent soft resin spacer 27 abuts to the upper end surface 11 of the reflector 2.

In FIG. 7(d), when the surface 29 of the first transparent soft resin spacer 27 abuts the upper end surface 11 of the reflector 2, the surface 29 of the first transparent soft resin spacer 27 presses the second transparent soft resin spacer 28 to cause resin spacer 28 to move. Therefore, the gap between the outer peripheral surface 20 of the reflector 2 and the inner peripheral surface 21 of the optical lens 14 is filled with the second transparent soft resin spacer 28. Further, the second transparent soft resin spacer 28 flows, due to the surface tension of the resin, along a portion of the outer peripheral surface 20 of the reflector 2, which portion is located between the lowermost surface 23 of the optical lens 14 and the circuit substrate 1. Hence, the outer peripheral surface 20 can be covered with the second transparent soft resin spacer 28. With this state maintained, heat can be applied thereto to cure the second transparent soft resin spacer 28.

The amount of the second transparent soft resin spacer 28 can be adjusted to an amount necessary and sufficient for covering the entire outer peripheral surface 20 of the reflector 2 when the resin spacer 28 is pressed.

As mentioned above, the recessed portion 13 has a region in which the first transparent soft resin spacer 27 is placed. Desirably, a portion of the inner peripheral surface 21 which portion corresponds to this region has a diameter larger than the outer diameter of the upper end surface 11 of the reflector 2.

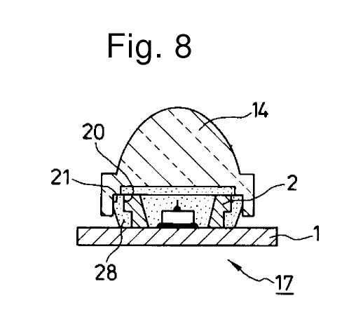

FIG. 8 is a cross-sectional view illustrating the semiconductor light-emitting device manufactured by means of the above manufacturing method. The reflector 2 provided on the circuit substrate 1 of the semiconductor light-emitting element-mounted body 17 can be integrated with the optical lens 14 via the second transparent soft resin spacer 28.

In particular, in this working example, the optical lens 14 can be integrated with the reflector 2 via the second transparent soft resin spacer 28 embedded in the gap between the outer peripheral surface 20 of the reflector 2 and the lower portion of the inner peripheral surface 21 of the optical lens 14. Therefore, the resin for the first transparent soft resin spacer 27 can be different from the resin for the second transparent soft resin spacer 28.

As described above, also in this working example, as in the above working examples, the transparent soft resin spacer can be configured to have an anchor effect and to provide a stress relaxation function, thus possibly preventing peeling caused by thermal stresses due to changes in outside temperature from occurring at the interfaces between the components. In this manner, a semiconductor light-emitting device having high light extraction efficiency and high reliability can be realized.

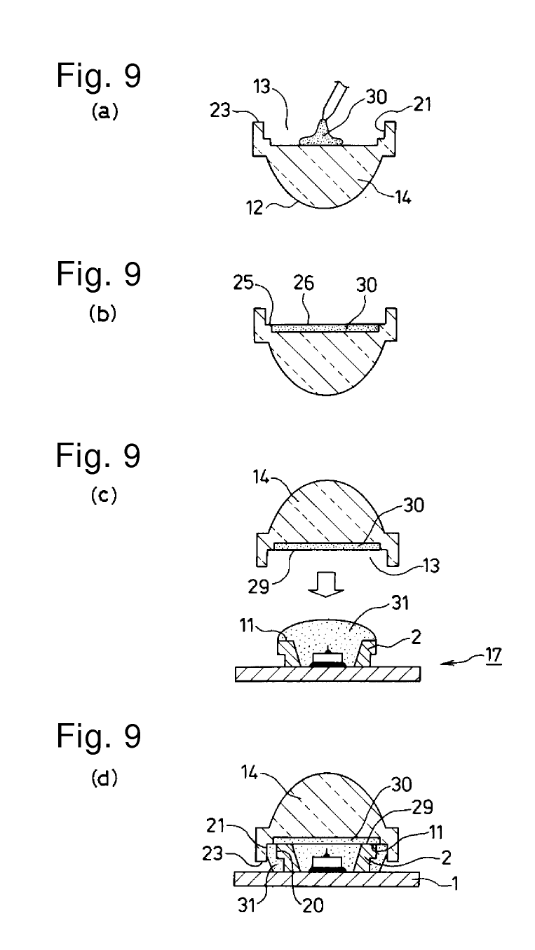

FIGS. 9(a)-(d) illustrate another working example of a method for manufacturing a semiconductor light-emitting device made in accordance with principles of the disclosed subject matter.

FIGS. 9(a) and (b) show a step portion that is provided in the recessed portion 13 of the optical lens 14. A third transparent soft resin spacer 30 that can be in a liquid state is injected into a region of the recessed portion 13 located on the lens surface side, and then is cured. In this instance, the transparent soft resin of this working example contains a wavelength conversion material.

In FIG. 9(c) a semiconductor light-emitting element-mounted body 17 that is completed through the steps shown in FIG. 3 is prepared (for example, as shown in FIG. 3(g)). However, in this working example, a fourth transparent soft resin spacer 31 can be employed as the resin injected into the recessed portion 5 of the reflector 2 of the semiconductor light-emitting element-mounted body 17. Then, the optical lens 14 that is constituted as described above is lowered with the recessed portion 13 facing the fourth transparent soft resin spacer 31 until the surface 29 of the third transparent soft resin spacer 30 abuts to the upper end surface 11 of the reflector 2.

As shown in FIG. 9(d), when the surface 29 of the third transparent soft resin spacer 30 abuts the upper end surface 11 of the reflector 2, the surface 29 of the third transparent soft resin spacer 30 presses the fourth transparent soft resin spacer 31 to cause this resin spacer 31 to move. Hence, the gap between the outer peripheral surface 20 of the reflector 2 and the inner peripheral surface 21 of the optical lens 14 is filled with the fourth transparent soft resin spacer 31.

Furthermore, the fourth transparent soft resin spacer 31 flows, due to the surface tension of the resin, along a portion of the outer peripheral surface 20 of the reflector 2 that is located between the lowermost surface 23 of the optical lens 14 and the circuit substrate 1. Hence, the outer peripheral surface 20 is covered with the fourth transparent soft resin spacer 31. With this state maintained, heat can be applied thereto to cure the fourth transparent soft resin spacer 31.

The amount of the fourth transparent soft resin spacer 31 can be adjusted to an amount necessary and sufficient for covering the entire outer peripheral surface 20 of the reflector 2 when the resin spacer 31 is pressed.

As mentioned above, the recessed portion 13 has a region in which the third transparent soft resin spacer 30 is placed. Desirably, a portion of the inner peripheral surface 21 that corresponds to this region has a diameter that is larger than the outer diameter of the upper end surface 11 of the reflector 2.

In this manufacturing method, the heat-curing step for the fourth transparent soft resin spacer 31 from the manufacturing steps for the semiconductor light-emitting element-mounted body shown in FIG. 3 can be omitted. Thus, the production efficiency can be improved.

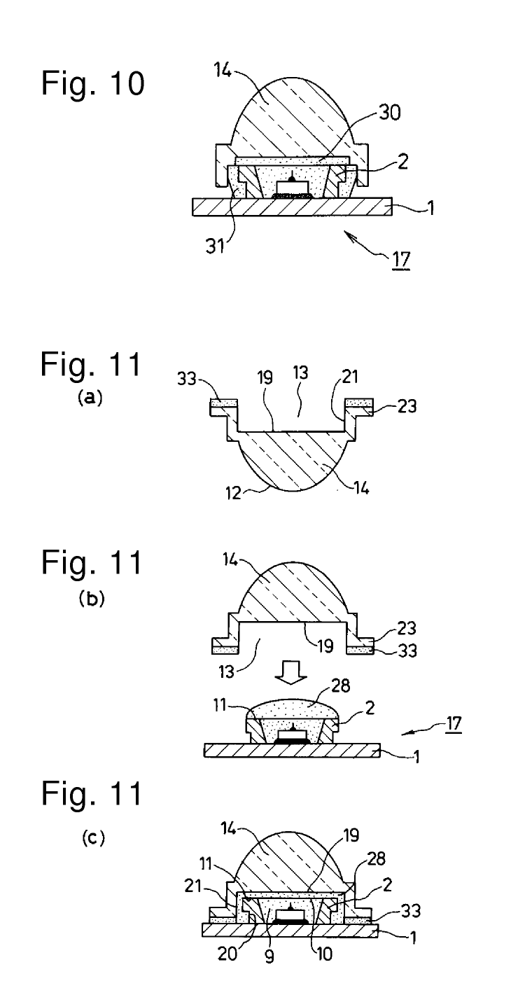

FIG. 10 is a cross-sectional view of a semiconductor light-emitting device produced by means of the above described manufacturing method. The reflector 2 provided on the circuit substrate 1 of the semiconductor light-emitting element-mounted body 17 can be integrated with the optical lens 14 via the fourth transparent soft resin spacer 31.

In this working example, the third transparent soft resin spacer serving also as the wavelength conversion layer can be placed on a side of the optical lens, and thus the distance between the semiconductor light-emitting element serving as a light-emitting source and the third transparent soft resin spacer is ensured. Therefore, the light emitted from the semiconductor light-emitting element can be projected onto the third transparent soft resin spacer uniformly over a wide area and then guided in the third transparent soft resin spacer and the optical lens. Hence, a light with little or no color unevenness can be emitted from the lens surface to the outside. Thus, according to the above configuration, a semiconductor light-emitting device having excellent optical characteristics can be realized.

As described above, also in this working example, as in the above working examples, the transparent soft resin spacer can have an anchor effect and provide a stress relaxation function to prevent peeling, caused by thermal stresses due to outside temperature changes, from occurring at the interfaces between the components. In this manner, a semiconductor light-emitting device having high light extraction efficiency and high reliability can be realized.

FIGS. 11(a)-(c) illustrate another working example of a method for manufacturing a semiconductor light-emitting device made in accordance with principles of the disclosed subject matter.

In FIG. 11(a) the optical lens 14 employed in this working example has a flange 23 and the recessed portion 13 has an inner peripheral surface 21. The flange 23 and the recessed portion 13 are formed on the side opposite to the lens surface 12. During manufacture, this optical lens 14 can be set on a jig (not shown) with the lens surface 12 facing downward. A fifth transparent soft resin spacer 33 can be placed on the bottom surface of the flange 23 by means of a dispenser, printing, dipping, or other method and can subsequently be heat-cured.

The optical lens 14 is configured to be placed on the circuit substrate 1 of the semiconductor light-emitting element-mounted body 17, as described later. Thus, the thickness of the fifth transparent soft resin spacer 33 is set such that, at the time of placement of the optical lens 14, the gap between the inner bottom surface 19 of the recessed portion 13 of the optical lens 14 and the upper end surface 11 of the reflector 2 of the semiconductor light-emitting element-mounted body 17 has a desired distance.

As shown in FIG. 11(b), a second transparent soft resin spacer 28 can be applied to the light emitting surface of the semiconductor light-emitting element-mounted body 17 and manufactured via the steps of FIG. 3 (as shown, for example, in FIG. 3(f)) such that the resin spacer 28 swells into a convex shape. Then, the optical lens 14 can be lowered with the recessed portion 13 facing the second transparent soft resin spacer 28 until the fifth transparent soft resin spacer 33 placed on the flange 23 of the optical lens 14 abuts the circuit substrate 1.

In FIG. 11(c) the fifth transparent soft resin spacer 33 abuts the circuit substrate 1, and the inner bottom surface 19 of the recessed portion 13 of the optical lens 14 can be configured to press against the second transparent soft resin spacer 28 to cause this resin spacer 28 to move. Hence, the second transparent soft resin spacer 28 fills the gap between the inner bottom surface 19 of the recessed portion 13 of the optical lens 14 and the upper end surface 11 of the reflector 2, the gap between the inner bottom surface 19 and the upper surface 10 of the fluorescent material-containing transparent resin 9, the gap between the outer peripheral surface 20 of the reflector 2 and the inner peripheral surface 21 of the optical lens 14, and the gap between the outer peripheral surface 20 and the fifth transparent soft resin spacer 33. With this state maintained, heat can be applied in order to cure the second transparent soft resin spacer 28.

The amount of the second transparent soft resin spacer 28 can be adjusted to an amount necessary and sufficient for covering the entire outer peripheral surface 20 of the reflector 2 when the resin spacer 28 is pressed.

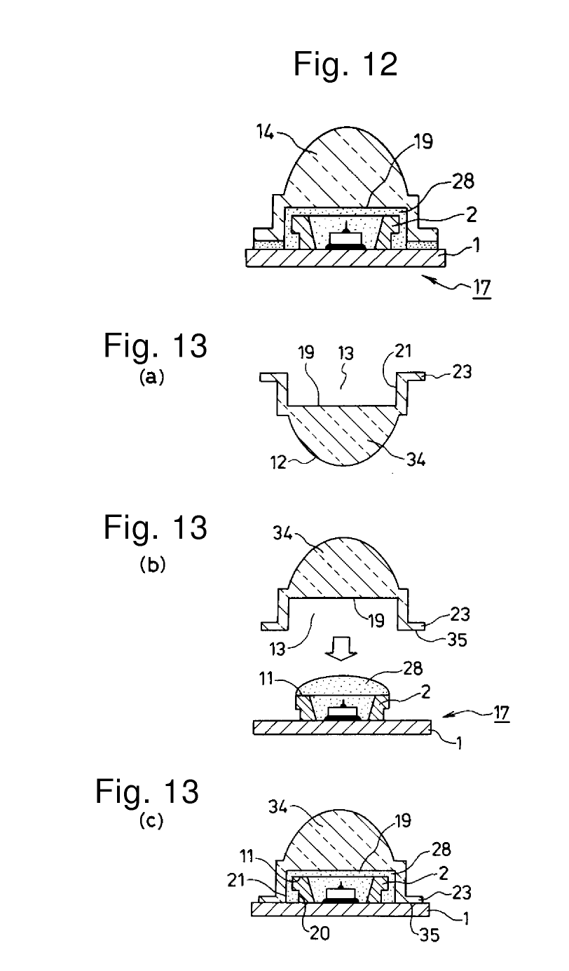

FIG. 12 is a cross-sectional view of a semiconductor light-emitting device produced by means of the above described manufacturing method. The reflector 2 provided on the circuit substrate 1 of the semiconductor light-emitting element-mounted body 17 can be integrated with the optical lens 14 via the second transparent soft resin spacer 28.

In this working example, the inner bottom surface 19 of the recessed portion 13 of the optical lens 14 can be configured to press against the second transparent soft resin spacer 28 that swells in a convex shape on the upper portion of the reflector 2 of the semiconductor light-emitting element-mounted body 17 to thereby cause this resin spacer 28 to move. By curing this spacer 28, the reflector 2 of the semiconductor light-emitting element-mounted body 17 can be integrated with the optical lens 14. Since the period/number of curing times can be reduced, the number of manufacturing steps can be reduced, whereby production efficiency can be improved.

As described above, also in this working example, as in the above working examples, the transparent soft resin spacer can have an anchor effect and a stress relaxation function to prevent peeling, caused by thermal stresses due to changing outside temperature, from occurring at the interfaces between the components. In this manner, a semiconductor light-emitting device having high light extraction efficiency and high reliability can be realized.

FIGS. 13(a)-(c) illustrates another working example of a method for manufacturing a semiconductor light-emitting device made in accordance with principles of the disclosed subject matter.

As shown in FIG. 13(a), an optical lens 34 of this working example can also include a flange 23 and recessed portion 13 having an inner peripheral surface 21. The flange 23 and the recessed portion 13 can be formed on a side opposite to the lens surface 12. Furthermore, the optical lens 34 of this working example can be made of a soft resin by means of a molding method, such as injection molding, by use of a metal mold.

The soft optical lens 34 can be placed on the circuit substrate 1 of the semiconductor light-emitting element-mounted body 17 as described later. Thus, the height of the flange 23 can be set such that, at the time of the placement of the soft optical lens 34, the gap between the inner bottom surface 19 of the recessed portion 13 of the soft optical lens 34 and the upper end surface 11 of the reflector 2 of the semiconductor light-emitting element-mounted body 17 has a desired distance.

In FIG. 13(b) the second transparent soft resin spacer 28 is shown as applied to the light emitting surface of the semiconductor light-emitting element-mounted body 17 and possibly manufactured via steps shown in FIG. 3 (see, for example, FIG. 3(f)) such that the resin spacer 28 swells into a convex shape. Then, the soft optical lens 34 can be lowered with the recessed portion 13 facing the second transparent soft resin spacer 28 until a bottom surface 35 of the flange 23 of the soft optical lens 34 abuts the circuit substrate 1 of the semiconductor light-emitting element-mounted body 17.

In FIG. 13(c), when the bottom surface 35 of the flange 23 of the soft optical lens 34 abuts the circuit substrate 1, the inner bottom surface 19 of the recessed portion 13 of the soft optical lens 34 can be configured to press the second transparent soft resin spacer 28 to cause this resin spacer 28 to move. Hence, the second transparent soft resin spacer 28 fills the gap between the inner bottom surface 19 of the recessed portion 13 of the soft optical lens 34 and the upper end surface 11 of the reflector 2, the gap between the inner bottom surface 19 and the upper surface 10 of the phosphor-containing transparent resin 9, and the gap between the outer peripheral surface 20 of the reflector 2 and the inner peripheral surface 21 of the soft optical lens 34. With this state maintained, heat can be applied in order to cure the second transparent soft resin spacer 28.

The amount of the second transparent soft resin spacer 28 can be adjusted to an amount necessary and sufficient for covering the entire outer peripheral surface 20 of the reflector 2 when the resin spacer 28 is pressed.

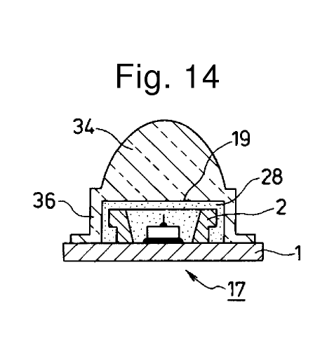

FIG. 14 is a cross-sectional view of a semiconductor light-emitting device produced by means of the above described manufacturing method. The reflector 2 provided on the circuit substrate 1 of the semiconductor light-emitting element-mounted body 17 can be integrated with the soft optical lens 34 via the second transparent soft resin spacer 28.

In this working example, the inner bottom surface 19 of the recessed portion 13 of the soft optical lens 34 can be configured to press against the second transparent soft resin spacer 28 that swells in a convex shape on the upper portion of the reflector 2 of the semiconductor light-emitting element-mounted body 17 to thereby cause this resin spacer 28 to move. By curing this spacer 28, the reflector 2 of the semiconductor light-emitting element-mounted body 17 can be integrated with the soft optical lens 34. Hence, since the period/number of curing times can be reduced, the number of manufacturing steps can be reduced, whereby production efficiency can be improved.

The bottom surface 35 of the flange 23 of the soft optical lens 34 can be configured to intimately contact the circuit substrate 1. Thus, when the second transparent soft resin spacer 28 expands or contracts due to temperature changes, a side surface 36 of the soft optical lens 34 also expands or contracts along with the expansion or contraction of the resin spacer 28. Therefore, thermal stresses in the second transparent soft resin spacer 28 are relaxed, and thus interfacial peeling can be prevented at the interfaces between the second transparent soft resin spacer 28 and other components.

As described above, also in this working example, as in the above working examples, the transparent soft resin spacer can have an anchor effect and a stress relaxation function to prevent peeling, caused by thermal stresses due to changing outside temperature, from occurring at the interfaces between the components. In this manner, a semiconductor light-emitting device having high light extraction efficiency and high reliability can be realized.

In the above described transparent soft resin spacers, desired optical characteristics may be obtained by adding light scatting particles and/or dye as appropriate. Furthermore, a wavelength conversion material may also be added thereto.

Furthermore, an LED element emitting light of a desired wavelength can be appropriately selected from among LED elements emitting light ranging from ultraviolet, visible, to infrared light, and can be employed as any of the above described semiconductor light-emitting elements.

Furthermore, in the above working examples, a hard optical lens and a soft optical lens are described as being employed as the optical lens. However, other lens may be employed in accordance with required specifications. In the case of a hard optical lens, a hard silicone resin, for example, can be employed as the material therefor. Further, in the case of a soft optical lens, a soft silicone resin, for example, can be employed as the material therefor. In addition, combinations of these soft and hard materials are contemplated for use as the optical lens.

In the above working examples, appropriately selecting one or more kinds of wavelength conversion materials can result in a semiconductor light-emitting device that emits light of desired color.

While there has been described what are at present considered to be exemplary embodiments of the disclosed subject matter, it will be understood that various modifications may be made thereto, and it is intended that the appended claims cover such modifications as fall within the true spirit and scope of the disclosed subject matter. All conventional art references described above are herein incorporated in their entirety by reference.

What is claimed is:

1. A semiconductor light-emitting device comprising:
a semiconductor light-emitting element-mounted body including a circuit substrate having a circuit provided on at least one surface thereof, a reflector located adjacent the circuit substrate and having a recessed portion in which a surface of the circuit substrate serves as an inner bottom surface thereof, a semiconductor light-emitting element including a light emission surface located in the recessed portion, and a resin-encapsulated portion located in the recessed portion;
an optical lens located in a forward light emission direction of the semiconductor light-emitting element, the optical lens including a light incident surface; and
a soft resin spacer portion located between the light incident surface of the optical lens and the light emission surface of the semiconductor light-emitting element-mounted body to thereby integrate the optical lens with the semiconductor light-emitting element-mounted body.

2. The semiconductor light-emitting device according to claim 1, wherein the resin-encapsulated portion contains a wavelength conversion material.

3. The semiconductor light-emitting device according to claim 2, wherein the reflector has an outer peripheral surface that has a shape extending outwardly in the light emission direction.

4. The semiconductor light-emitting device according to claim 3, wherein the outer peripheral surface is inclined outwardly within a range of 2 to 30° with respect to an optical axis of the semiconductor light-emitting element.

5. The semiconductor light-emitting device according to claim 3, wherein a thickness of the soft resin spacer portion is equal to or greater than 30% of a distance between the surface of the circuit substrate and an upper end surface of the reflector.

6. The semiconductor light-emitting device according to claim 1, wherein the reflector has at least two outer peripheral surface portions having different diameters, and wherein the outer diameter of a lower outer peripheral surface portion on a side closer to the circuit substrate is smaller than the outer diameter of an upper outer peripheral surface portion on an opening side of the reflector.

7. The semiconductor light-emitting device according to claim 6, wherein the difference in outer diameter between the upper outer peripheral surface portion and the lower outer peripheral surface portion of the reflector is within a range of 0.1 to 2.0 mm.

8. The semiconductor light-emitting device according to claim 6, wherein a distance between the light incident surface of the optical lens and a step portion in an outer peripheral surface of the reflector is within a range of 0.1 to 1.0 mm.

9. The semiconductor light-emitting device according to claim 1, wherein the optical lens has a lens surface and the light incident surface is located on a side opposite to the lens surface, the light incident surface has a recessed portion.

10. The semiconductor light-emitting device according to claim 9, wherein a distance between a bottom surface of the recessed portion of the optical lens and an upper end surface of the reflector is within a range of 0.1 to 1.0 mm.

11. A method for manufacturing the semiconductor light-emitting device according to claim 9, the method comprising:
supplying a resin material to the recessed portion of the optical lens to form the soft resin spacer portion;
placing the optical lens at a predetermined position;
pressing the reflector of the semiconductor light-emitting element-mounted body against the resin material of the soft resin spacer portion to bury the reflector in the resin material;
heat-curing the resin material of the soft resin spacer portion while keeping a bottom surface of the recessed portion of the optical lens and an upper end surface of the reflector separated by a predetermined distance.

12. A semiconductor light-emitting device comprising:
a semiconductor light-emitting element-mounted body including a circuit substrate having a circuit provided on at least one surface thereof, a reflector located adjacent the circuit substrate and having a recessed portion in which a surface of the circuit substrate serves as an inner bottom surface thereof, a semiconductor light-emitting element including a light emission surface located in the recessed portion, and a resin-encapsulated portion located in the recessed portion;
an optical lens having a light incident surface and being located in a forward light emission direction of the semiconductor light-emitting element, the optical lens having a flange in a periphery of the light incident surface;
a first soft resin spacer portion located between the light incident surface of the optical lens and the light emission surface of the semiconductor light-emitting element-mounted body to thereby integrate the optical lens with the semiconductor light-emitting element-mounted body; and
a second soft resin spacer portion located between the flange and the circuit substrate.

13. The semiconductor light-emitting device according to claim 12, wherein the resin-encapsulated portion contains a wavelength conversion material.

14. The semiconductor light-emitting device according to claim 13, wherein the optical lens has a lens surface and the light incident surface is located on a side opposite to the lens surface, the light incident surface has a recessed portion.

15. The semiconductor light-emitting device according to claim 14, wherein a distance between a bottom surface of the recessed portion of the optical lens and an upper end surface of the reflector is within a range of 0.1 to 1.0 mm.

16. The semiconductor light-emitting device according to claim 12, wherein at least one of light scattering particles and dye is mixed with at least one of the first soft resin spacer portion and the second soft resin spacer portion.

17. A method for manufacturing the semiconductor light-emitting device according to claim 12, the method comprising:
supplying a resin material onto the reflector and the resin encapsulated portion to form the soft resin spacer portion;
placing the semiconductor light-emitting element-mounted body at a predetermined position;
pressing the resin material of the first soft resin spacer portion with the light incident surface of the lens; and
heat-curing the resin material of the first soft resin spacer portion while keeping a bottom surface of the recessed portion of the optical lens and an upper end surface of the reflector separated by a predetermined distance.

18. A semiconductor light-emitting device comprising:
a semiconductor light-emitting element-mounted body including a circuit substrate having a circuit provided on at least one surface thereof, a reflector located adjacent the circuit substrate and having a recessed portion in which a surface of the circuit substrate serves as an inner bottom surface thereof, a semiconductor light-emitting element including a light emission surface and located in the recessed portion, and a resin-encapsulated portion located in the recessed portion;
an optical lens having a light incident surface and being located in a forward light emission direction of the semiconductor light-emitting element; and
a soft resin spacer portion located between the light incident surface of the optical lens and the light emission surface of the semiconductor light-emitting element-mounted body to thereby integrate the optical lens with the semiconductor light-emitting element-mounted body, wherein
the optical lens has a recessed portion on the light incident surface, the recessed portion has at least two inner peripheral surface portions having different inner diameters, and, among the at least two inner peripheral surface portions, an inner peripheral surface portion on an opening side of the recessed portion of the optical lens has an inner diameter that is larger than an inner diameter of an inner peripheral surface portion located closer to a lens surface side of the optical lens.

19. The semiconductor light-emitting device according to claim 18, wherein, among the at least two inner peripheral surface portions, the smaller inner diameter inner peripheral surface portion has an inner diameter that is larger than an outer diameter of an upper end surface of the reflector.

20. The semiconductor light-emitting device according to claim 18, wherein a transparent soft resin spacer portion is located in the smaller inner diameter inner peripheral surface portion of the recessed portion of the optical lens.

21. The semiconductor light-emitting device according to claim 18, wherein a transparent soft resin spacer portion is located in the smaller inner diameter inner peripheral surface portion of the recessed portion of the optical lens, and the soft resin spacer portion contains a wavelength conversion material.

22. A method for manufacturing the semiconductor light-emitting device according to claim 18, the method comprising:
supplying a resin material onto the reflector and the resin encapsulated portion to form the soft resin spacer portion;
placing the semiconductor light-emitting element-mounted body at a predetermined position;
pressing the resin material of the soft resin spacer portion with the light incident surface of the optical lens; and
heat-curing the resin material of the soft resin spacer portion while keeping a bottom surface of the recessed portion of the optical lens and an upper end surface of the reflector separated by a predetermined distance.

23. The semiconductor light-emitting device according to claim 1, wherein the soft resin spacer portion is a soft silicone resin.

24. The semiconductor light-emitting device according to claim 1, wherein the soft resin spacer portion includes a transparent resin.

25. The semiconductor light-emitting device according to claim 12, wherein at least one of the first soft resin spacer portion and the second soft resin spacer portion is a soft silicone resin.

26. The semiconductor light-emitting device according to claim 12, wherein at least one of the first soft resin spacer portion and the second soft resin spacer portion includes a transparent resin.

27. The semiconductor light-emitting device according to claim 18, wherein the soft resin spacer portion is a soft silicone resin.

28. The semiconductor light-emitting device according to claim 18, wherein the soft resin spacer portion includes a transparent resin.
